(19) United States
(12) Patent Application Publication
(10) Pub. No.: US 2025/0008831 A1
(43) Pub. Date: Jan. 2, 2025

(54) APPARATUS AND METHOD OF MANUFACTURING DEPOSITION MASK

(71) Applicant: Samsung Display Co., Ltd., Yongin-si (KR)

(72) Inventors: Kyongho Hong, Yongin-si (KR); Myungkyu Kim, Yongin-si (KR); Sungho Park, Yongin-si (KR); Changkon Park, Yongin-si (KR); Sukbeom You, Yongin-si (KR)

(21) Appl. No.: 18/620,063

(22) Filed: Mar. 28, 2024

(30) Foreign Application Priority Data
Jun. 27, 2023 (KR) 10-2023-0082892

(51) Int. Cl. H10K 71/16; H01L 21/027; H10K 59/35

(52) U.S. Cl. CPC H10K 71/166; H01L 21/0271; H10K 59/35

(57) ABSTRACT

An apparatus for manufacturing a mask is provided. The apparatus includes: a stage body portion tilted with respect to a gravitational direction and configured to receive a mask frame having opening sits thereon; a contact portion protruding from one surface of the stage body portion toward the mask frame; and a moving portion configured to move the contact portion.

### CROSS-REFERENCE TO RELATED APPLICATION

The present application claims priority to and the benefit of Korean Patent Application No. 10-2023-0082892, filed on Jun. 27, 2023, in the Korean Intellectual Property Office, the entire disclosure of which is incorporated herein by reference.

### BACKGROUND

### 1. Field

Aspects of embodiments of the present disclosure relate to an apparatus and a method of manufacturing a deposition mask.

### 2. Description of the Related Art

Display apparatuses visually display data. Display apparatuses may display images by using light-emitting diodes. The purpose and structure of display apparatuses have been diversified, and a structure that may be bent to have a preset angle from a flat state has also been developed.

Display apparatuses may include a plurality of pixels to display images. In this case, an intermediate layer including an emission layer may be arranged in the plurality of pixels having a pattern shape. The pattern shape should be disposed on a substrate according to the kind of intermediate layer.

### SUMMARY

The quality of images displayed by a display apparatus is determined depending on how accurately an intermediate layer is disposed when disposing the intermediate layer having a pattern shape on a substrate. For this purpose, transformation of a mask assembly used to form the intermediate layer having (or in) a pattern shape is an important issue when forming the intermediate layer. Embodiments of the present disclosure include an apparatus and a method of manufacturing a mask with a reduced transformation of a mask assembly.

Additional aspects and features of the present disclosure will be set forth, in part, in the description that follows and, in part, will be apparent from the description or may be learned by practice of the described embodiments of the present disclosure.

According to an embodiment of the present disclosure, an apparatus for manufacturing a mask includes a stage body portion tilted with respect to a gravitational direction and configured to receive a mask frame having opening sits thereon, a contact portion protruding from one surface of the stage body portion toward the mask frame, and a moving portion configured to move the contact portion.

At least a portion of the contact portion may overlap the mask frame.

The contact portion may be arranged to correspond to an edge of the mask frame.

The contact portion may include a magnet.

The magnet of the contact portion may be configured to exhibit no magnetism while a current flows therethrough.

The moving portion may be between the contact portion and the stage body portion.

The moving portion may include a translation element.

The moving portion may include an elastic body corresponding to at least one of moving directions of the contact portion and may be configured to exhibit an elastic force to the contact portion. The contact portion may have a plurality of surfaces, the elastic body may be provided in a plurality, and each surface of the contact portion may be connected to at least one elastic body corresponding thereto.

A number of elastic bodies connected to one of the plurality of surfaces may be different from a number of elastic bodies connected to another one of the plurality of surfaces.

The apparatus may further include a second supporter protruding from one surface of the stage body portion and configured to support one surface of the mask frame.

According to another embodiment of the present disclosure, a method of manufacturing a mask includes arranging a mask frame having an opening on a mask stage that is tilted with respect to a gravitational direction and attaching a mask sheet to the mask frame. The mask stage includes a stage body portion, a contact portion protruding from one surface of the stage body portion toward the mask frame, and a moving portion configured to move the contact portion.

The method may further include seating the mask frame on a second supporter protruding from one surface of the mask stage.

The method may further include allowing the mask frame to be in close contact with the contact portion by using a magnet provided to the contact portion.

The magnet of the contact portion may be configured to exhibit no magnetism while a current flows therethrough.

The method may further include stretching the mask frame.

The moving portion may include an elastic body configured to apply an elastic force and corresponding to at least one of moving directions of the contact portion.

The contact portion may be arranged to correspond to an edge of the mask frame.

At least a portion of the contact portion may overlap the mask frame.

The method may further include moving the mask frame relative to the mask stage.

### BRIEF DESCRIPTION OF THE DRAWINGS

The above and other aspects and features of the present disclosure will be more apparent from the following description taken in conjunction with the accompanying drawings, in which:

FIG. 1 is a schematic cross-sectional view of a portion of an apparatus for manufacturing a display apparatus according to an embodiment;

FIG. 2 is a schematic perspective view of a portion of an apparatus for manufacturing a mask according to an embodiment;

FIG. 3 is a schematic front view of a portion of an apparatus for manufacturing a mask according to an embodiment;

FIGS. 4A and 4B are schematic cross-sectional views of a portion of an apparatus for manufacturing a mask according to embodiments;

FIG. 5 is an enlarged cross-sectional view of a portion of an apparatus for manufacturing a mask according to an embodiment;

FIGS. 6A and 6B are enlarged front views of a portion of an apparatus for manufacturing a mask according to embodiments;

FIGS. 7A and 7B are schematic cross-sectional views showing states of an operating process of an apparatus for manufacturing a mask according to an embodiment;

FIGS. 8A to 8C are schematic front views showing steps of a method of manufacturing a mask according to an embodiment;

FIG. 9 is a schematic plan view of a display apparatus according to an embodiment; and

FIG. 10 is a cross-sectional view taken along the line X-X′ of FIG. 9.

### DETAILED DESCRIPTION

Reference will now be made, in detail, to embodiments, examples of which are illustrated in the accompanying drawings. In this regard, the described embodiments may have different forms, and the present disclosure should not be construed as being limited to the descriptions (or embodiments) set forth herein. Accordingly, embodiments of the present disclosure are merely described below, by referring to the figures, to explain aspects and features of the present description.

Because the present disclosure allows for various changes and numerous embodiments, some embodiments will be illustrated in the drawings and described in the written description. Aspects and features of the present disclosure, and methods for achieving them, will be clarified with reference to embodiments described below in detail with reference to the drawings. However, the present disclosure is not limited to the following embodiments and may be embodied in various forms.

Hereinafter, embodiments will be described with reference to the accompanying drawings, in which like reference numerals refer to like elements throughout and a repeated description thereof is omitted.

While such terms as “first” and “second” may be used to describe various elements, such elements are not limited to such terms. Such terms are used to distinguish one element from another.

The singular forms “a” and “an” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the present disclosure is not necessarily limited thereto.

In the case where a certain embodiment may be implemented differently, a specific process order may be performed in the order different from the described order. As an example, two processes successively described may be performed concurrently (or simultaneously) or performed in the opposite order.

In the present specification, “A and/or B” means A or B, or A and B. In the present specification, “at least one of A and B” means A or B, or A and B. Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that when a layer, region, or element is referred to as being “connected” to another layer, region, or element, it may be “directly connected” to the other layer, region, or element or may be “indirectly connected” to the other layer, region, or element with another layer, region, or element located therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

A first direction, a second direction, and a third direction are not limited to three axes of the rectangular coordinate system and may be interpreted in a broader sense. For example, the first direction, the second direction, and the third direction may be perpendicular to one another or may represent different orientations that are not perpendicular to one another.

An x direction, a y direction, and a z direction are not limited to three axes of the rectangular coordinate system and may be interpreted in a broader sense. For example, the x direction, the y direction, and the z direction may be perpendicular to one another or may represent different orientations that are not perpendicular to one another.

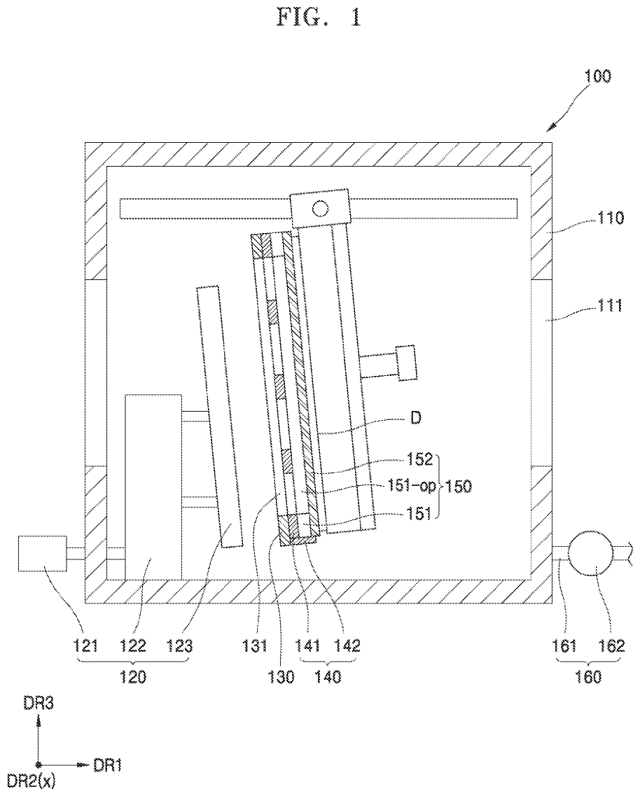

FIG. 1 is a schematic cross-sectional view of a portion of an apparatus 100 for manufacturing a display apparatus according to an embodiment.

Referring to FIG. 1, the apparatus 100 for manufacturing a display apparatus may be a deposition apparatus in which deposition is performed.

The apparatus 100 for manufacturing a display apparatus may be configured to perform deposition on a display substrate D of a display apparatus. The apparatus 100 for manufacturing a display apparatus may include a chamber 110, a deposition source 120, a first supporter 130, a first support block 140, a mask assembly 150, and a pressure adjustor 160.

The chamber 110 may have an open portion such that the display substrate D, which is an object to be processed, is introduced into the chamber 110 and discharged to the outside of the chamber 110. An opening/closing portion 111, such as a gate valve, may be disposed in the open portion of the chamber 110. In such an embodiment, because the opening/closing portion 111 is selectively opened, the display substrate D, which is an object to be processed, may be loaded into the chamber 110 and unloaded to the outside of the chamber 110.

The deposition source 120 may be configured to supply a deposition material toward the mask assembly 150. In such an embodiment, the deposition source 120 may include a deposition material supply portion 121, a source portion 122, and a nozzle portion 123.

The deposition material supply portion 121 may be configured to receive a deposition material and supply the deposition material to the source portion 122. In such embodiments, the deposition material supply portion 121 may be disposed outside or inside the chamber 110. The deposition material supply portion 121 may be configured to supply a deposition material to the source portion 122 by (or by including) a pump and the like. Hereinafter, for convenience of description, an embodiment in which the deposition material supply portion 121 is disposed outside the chamber 110 is primarily described in detail.

The source portion 122 may be disposed inside the chamber 110 and connected to the deposition material supply portion 121 to evaporate or sublimate the deposition material. The source portion 122 may include a crucible in which the deposition material is accommodated and a heater for heating the crucible.

The nozzle portion 123 may be connected to the source portion 122. In such an embodiment, the nozzle portion 123 may be connected to the source portion 122 through a pipe and the like. At least one nozzle portion 123 may be included in the apparatus 100 for manufacturing a display apparatus. The nozzle portion 123 may be formed in a rectangular pillar shape. In such an embodiment, a long side portion of the nozzle portion 123 may be disposed oblique with respect to a third direction DR3. For example, an angle at which the nozzle portion 123 is tilted may be equal or similar to an angle at which the mask assembly 150 is tilted. The nozzle portion 123 may include a spray portion through which the deposition material is sprayed. The spray portion may have a circular hole shape. In another embodiment, the spray portion may have a hole (or opening) having a long slot shape. In another embodiment, the spray portion may have a form protruding from the outer surface of the nozzle portion 123.

The first supporter 130 and the first support block 140 may support the mask assembly 150. In such an embodiment, the first supporter 130 and the first support block 140 may support the mask assembly 150 in a tilted state with respect to the lower surface (or the ground) of the chamber 110. For example, the mask assembly 150 may be disposed inside the chamber 110 in an upright state, and the first supporter 130 and the first support block 140 may maintain the mask assembly 150 in the upright state.

The first supporter 130 may be formed as a window frame with an opening 131 in a central portion of the first supporter 130. The opening 131 may have a shape through which the deposition material supplied from the deposition source 120 may pass. One surface (e.g., a surface facing the first support block 140) of the first supporter 130 may have a flat shape. The first supporter 130 may be connected to the chamber 110. In such an embodiment, the first supporter 130 may be fixed to the lower surface of the chamber 110 or connected to the inner surface of the chamber 110 through a separate structure. Hereinafter, for convenience of description, an embodiment in which the first supporter 130 is fixed to the lower surface of the chamber 110 is primarily described.

The first support block 140 may be provided in a plurality and disposed on the surface of the first supporter 130. The plurality of first support blocks 140 may include a 1-1 support block 141 and a 1-2 support block 142. In such an embodiment, the 1-1 support block 141 and the 1-2 support block 142 may support another surface (e.g., another surface of the mask frame 151) of the mask assembly 150. As an example, the 1-1 support block 141 may support the rear surface (e.g., the rear surface of the mask frame 151) of the mask assembly 150. That is, the 1-1 support block 141 may support one surface of the mask assembly 150 facing the first supporter 130. The 1-1 support block 141 may be provided in a plurality. In such an embodiment, the plurality of 1-1 support blocks 141 may be spaced apart from each other along the outer surface of the first supporter 130. Each of the 1-1 support blocks 141 may be disposed between the first supporter 130 and the mask assembly 150 to support the mask assembly 150. In other words, between the first supporter 130 and the mask assembly 150, there may be a space in which the 1-1 support block 141 is disposed and an empty space between the 1-1 support blocks 141 (e.g., between adjacent ones of the 1-1 support blocks 141).

The 1-2 support block 142 may be disposed on the first supporter 130 to support the lower surface and/or the lateral surface (e.g., the lower surface or the lateral surface of the mask frame 151) of the mask assembly 150. As an example, the 1-2 support block 142 may support one surface of the mask assembly 150 not supported by the 1-1 support block 141. In some embodiments, the 1-2 support block 142 may be disposed on only the lower portion of the first supporter 130. In one embodiment, only one 1-2 support block 142 may be provided and disposed on the outer surface of the first supporter 130, or in another embodiment, similar to the 1-1 support blocks 141, the 1-2 support block 142 may be provided in a plurality and arranged spaced apart from each other along the outer surface of the first supporter 130.

The first supporter 130 and the first support block 140 may support the mask assembly 150 in a tilted state. In the titled state, the upper portion of the mask assembly 150 is further inclined toward (e.g., is nearer to) the deposition source 120 than the lower portion of the mask assembly 150 is. For example, a tilted (or tilt) angle of the mask assembly 150 may denote an angle between a line (e.g., a line segment extending in the third direction DR3) perpendicular to the lower surface (or the ground) of the chamber 110 and the flat surface of the mask assembly 150. That is, a tilted angle of the mask assembly 150 may denote (or may refer to) an angle at which the mask assembly 150 is inclined with respect to the direction of gravity.

The mask assembly 150 may include the mask frame 151 and a mask sheet 152. The mask frame 151 may have an opening 151-op in the center thereof. For example, the mask frame 151 may be formed to be similar to (e.g., to have a similar shape and configuration as) the first supporter 130.

One surface of the mask frame 151 may be formed to be flat. As an example, one surface of the mask frame 151 that is in contact with the mask sheet 152 may be flat.

The mask sheet 152 may be arranged to shield (e.g., to overlap or to cover) the opening 151-op in the mask frame 151. In such an embodiment, one mask sheet 152 may be provided. In such an embodiment, the mask sheet 152 may shield the opening 151-op entirely. In another embodiment, a plurality of mask sheets 152 may be provided. The plurality of mask sheets 152 may be arranged to be adjacent to each other and arranged in one direction. As an example, a lengthwise direction of each mask sheet 152 may be a direction (e.g., a direction tilted from the third direction DR3 of FIG. 1) tilted at an angle (e.g., a preset or predetermined angle) with respect to a straight line perpendicular to the lower surface of the chamber 110. In addition, the direction in which the plurality of mask sheets 152 are arranged may be a second direction DR2 shown in FIG. 1. In such an embodiment, because the plurality of mask sheets 152 are arranged to be adjacent to each other, the mask sheets 152 may shield (e.g., may together shield) the opening 151-op in the mask frame 151. Hereinafter, for convenience of description, an embodiment in which the mask sheet 152 is provided in a plurality is primarily shown and described in detail.

The mask assembly 150 may further include a support member disposed in the opening in the mask frame 151 and supporting the mask sheet 152. In such an embodiment, the support member may have a shape in which a portion extending in the second direction DR2 crosses a portion extending in a direction tilted from the third direction DR3.

The pressure adjustor 160 may be connected to the chamber 110 and configured to adjust the inner pressure of the chamber 110. The pressure adjustor 160 may include a pipe 161 connected to the chamber 110 and a pump 162 connected to the pipe 161.

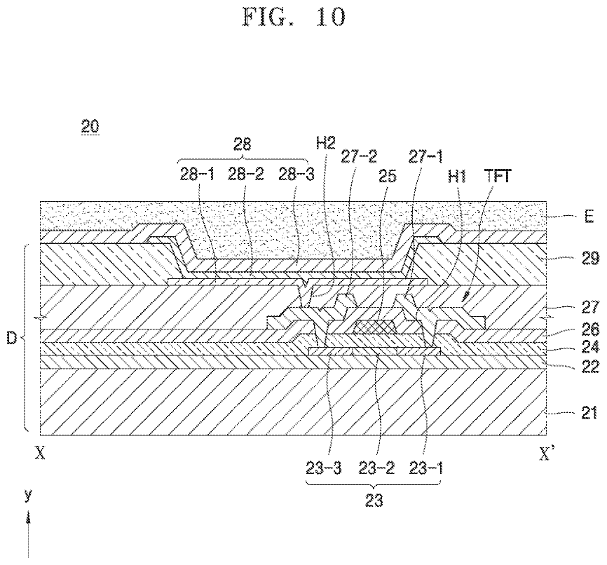

The display substrate D, which is an object of the apparatus 100 for manufacturing a display apparatus to be processed, may be a form corresponding to an arbitrary one of operations in which layers from a substrate 21 (see, e.g., FIG. 10) to a pixel-defining layer 29 (see, e.g., FIG. 10), described below with reference to FIG. 10, are sequentially stacked. As an example, the display substrate D may be a form in which only the substrate 21 is disposed, a form in which the substrate 21 up to a passivation layer 27 are disposed, or a form in which the substrate 21 up to the pixel-defining layer 29 are disposed.

Transformation due to the weight of the mask assembly 150 may be less

when the mask assembly 150 is disposed as described above than when the mask assembly 150 is disposed completely flat with respect to the lower surface (or the ground) of the chamber 110. Furthermore, compared to when the mask assembly 150 is disposed vertical with respect to the lower surface of the chamber 110, because transformation of the mask assembly 150 is in a constant (or substantially constant) range, deposition quality may be improved. That is, when the mask assembly 150 is disposed horizontal with respect to the lower surface of the chamber 110, the central portion of the mask sheet 153 may sag due to the weight of elements of the mask assembly 150. In this case, the deposition material passing through the mask sheet 153 may not be deposited on the display substrate D in a precise pattern. In addition, when the mask assembly 150 is disposed vertical with respect to the lower surface (or the ground) of the chamber 110, the upper end of the mask frame 151 may warp and, thus, may not support the mask sheet 153. Accordingly, the deposition material may not be deposited on the display substrate D in a precise pattern. However, when deposition is performed with the mask assembly 150 tilted with respect to the lower surface of the chamber 110, because the above-mentioned issue is reduced, the deposition material may be deposited on the display substrate D in a precise pattern.

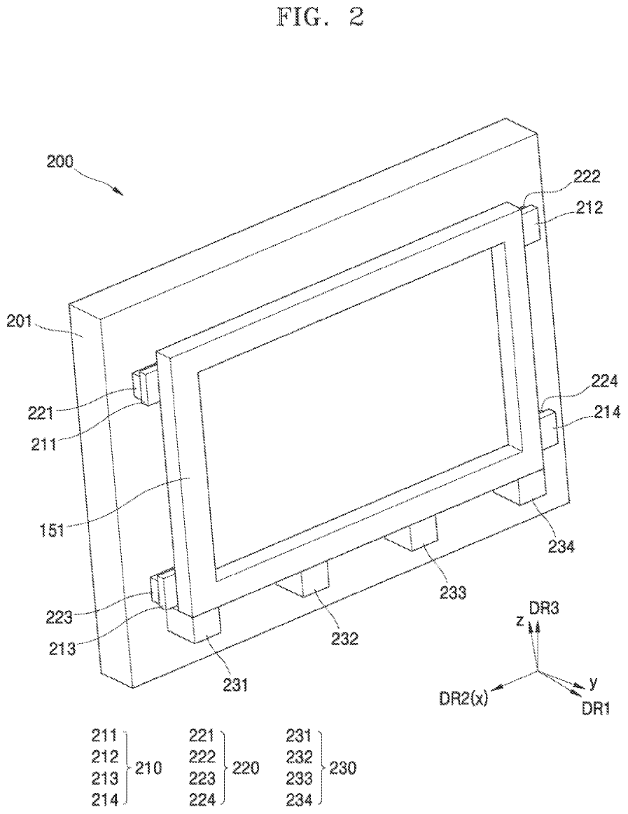

FIG. 2 is a schematic perspective view of a portion of an apparatus for manufacturing a mask according to an embodiment.

The first direction to the third direction DR1, DR2, and DR3 shown in FIG. 2 may be the same directions as the first direction to the third direction shown above in FIG. 1. In embodiments below, a z direction may be a direction tilted by an angle from the third direction DR3, a y direction may be a direction tilted with respect to the first direction DR1 by the same amount that the z direction is tilted with respect to the third direction DR3, and an x direction may be the same direction as the second direction

DR2. An apparatus 200 for manufacturing a mask may remain tilted with respect to the third direction DR3, and in this case, a length direction of the apparatus 200 for manufacturing a mask may be the x direction, a height direction may be the z direction, and a thickness direction may be the y direction.

Referring to FIG. 2, the apparatus 200 for manufacturing a mask may include a stage body portion 201, a contact portion 210, a moving portion 220, and a second supporter 230.

The stage body portion 201 may support the mask frame 151 during a process of manufacturing the mask assembly 150 (see, e.g., FIG. 1). The stage body portion 201 may be disposed to be tilted with respect to one direction (e.g., the third direction DR3 or the direction of gravity) and may provide a base on which the mask frame 151 may be seated. In an embodiment, the stage body portion 201 may extend in a direction (e.g., the z direction) tilted from the third direction DR3 and may have an approximately hexahedron shape having a thickness (e.g., a preset or predetermined thickness) and protruding toward a direction (e.g., the y direction) tilted from the first direction DR1.

The contact portion 210 may support one surface of the mask frame 151 in a direction (e.g., the y direction) perpendicular to one direction (e.g., the z direction) tilted with respect to the third direction DR3 (or the direction of gravity). As an example, the contact portion 210 may support one surface of the mask frame 151 facing the stage body portion 201. In this case, the contact portion 210 may be a portion that is in direct contact with the mask frame 151. The contact portion 210 may be in partial contact with the mask frame 151 or may be in entire (or complete) contact with the mask frame 151. Hereinafter, for convenience of description, an embodiment in which a portion of the contact portion 210 is in partial contact with the mask frame 151 is primarily described in detail.

The contact portion 210 may include a plurality of contact blocks of an island type (or in an island arrangement). As an example, the contact portion 210 may include first to fourth contact blocks 211, 212, 213, and 214. The first to fourth contact blocks 211, 212, 213, and 214 may be arranged spaced apart from each other in the z direction and/or the x direction (or the second direction DR2). Hereinafter, an embodiment in which the contact portion 210 includes four contact blocks is primarily described in detail.

The moving portion 220 may be disposed between the stage body portion 201 and the contact portion 210. The moving portion 220 may move the contact portion 210 during a process of manufacturing the mask assembly 150 (see, e.g., FIG. 1).

The moving portion 220 may include a plurality of moving blocks. As an example, the moving portion 220 may include first to fourth moving blocks 221, 222, 223, and 224 respectively corresponding to the first to fourth contact blocks 211, 212, 213, and 214. The first to fourth moving blocks 221, 222, 223, and 224 may be arranged spaced apart from each other in the z direction and/or the x direction (or the second direction DR2). The first to fourth moving blocks 221, 222, 223, and 224 may be arranged to respectively overlap the first to fourth contact blocks 211, 212, 213, and 214. The first to fourth moving blocks 221, 222, 223, and 224 may be respectively coupled to the first to fourth contact blocks 211, 212, 213, and 214. The first to fourth moving blocks 221, 222, 223, and 224 may move independently from each other.

The second supporter 230 may protrude in the y direction from the stage body portion 201 to support one surface of the mask frame 151. As an example, the second supporter 230 may support one surface (e.g., the lower surface) of the mask frame 151 that is not supported by the contact portion 210. The second supporter 230 may have a shape including one second support block extending in the x direction (or the second direction DR2) or may have a shape in which a plurality of second support blocks are spaced apart from each other and arranged in the x direction (or the second direction DR2). Hereinafter, for convenience of description, an embodiment in which a plurality of second support blocks are spaced apart from each other and arranged in the x direction (or the second direction DR2) is primarily described in detail.

The second supporter 230 may include a plurality of second support blocks. As an example, the second supporter 230 may include 2-1 to 2-4 support blocks 231, 232, 233, and 234. The 2-1 to 2-4 support blocks 231, 232, 233, and 234 may be disposed at the lower end of the stage body portion 201 and may protrude in the y direction from the stage body portion 201. The 2-1 to 2-4 support blocks 231, 232, 233, and 234 may be arranged spaced apart from each other in the x direction (or the second direction DR2). The 2-1 to 2-4 support blocks 231, 232, 233, and 234 may support the lower surface of the mask frame 151. As an example, the 2-1 to 2-4 support blocks 231, 232, 233, and 234 may support the mask frame 151 in a +z direction.

Similar to the first supporter 130 and the first support block 140, shown in FIG. 1, the stage body portion 201, the contact portion 210, and the second supporter 230 may support the mask frame 151 in a state tilted with respect to the third direction DR3.

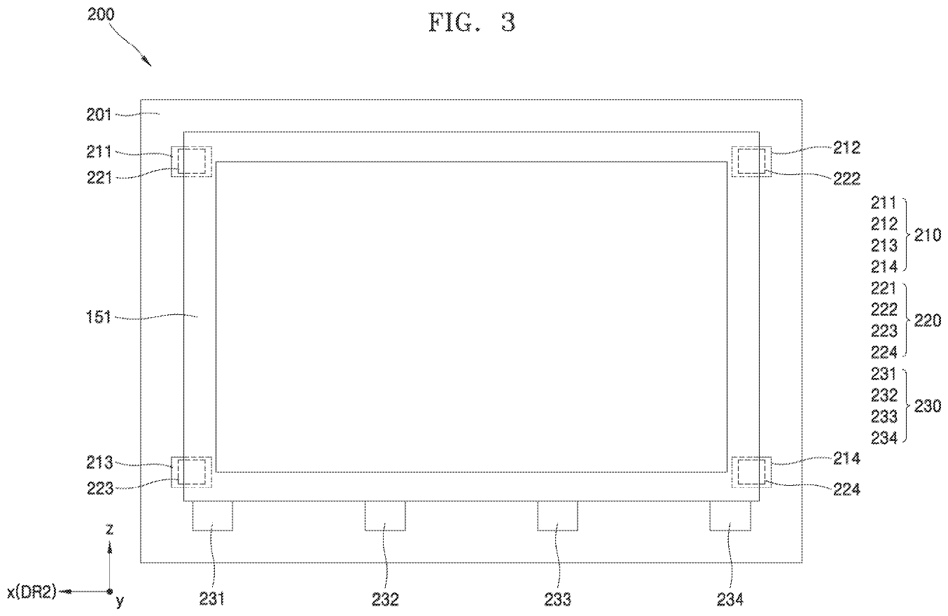

FIG. 3 is a schematic front view of a portion of an apparatus for manufacturing a mask according to an embodiment.

Hereinafter, from among the characteristics of the apparatus 200 for manufacturing a mask, characteristics already described with reference to FIG. 2 are not repeated while other characteristics are primarily described.

Referring to FIG. 3, a portion of the contact portion 210 may overlap the mask frame 151. As an example, a portion of each of the first to fourth contact blocks 211, 212, 213, and 214 may overlap the mask frame 151. In such an embodiment, the first to fourth contact blocks 211, 212, 213, and 214 may be completely hidden by the mask frame 151 and may only partially overlap the mask frame 151. As an example, a width (e.g., a length in the x direction) of the first to fourth contact blocks 211, 212, 213, and 214 may be less than a width of the mask frame 151. In another embodiment, the first to fourth contact blocks 211, 212, 213, and 214 may not be completely hidden by the mask frame 151. As an example, a width (e.g., a length in the x direction) of the first to fourth contact blocks 211, 212, 213, and 214 may be greater than a width of the mask frame 151.

Although an embodiment in which a portion of the contact portion 210 overlaps the mask frame 151 is shown in FIG. 3, the present disclosure is not limited thereto, and the contact portion 210 may completely overlap the mask frame 151. In such an embodiment, when viewed in one direction (e.g., the y direction), the contact portion 210 may be completely hidden by the mask frame 151.

The moving portion 220 may overlap the contact portion 210. As an example, the first to fourth moving blocks 221, 222, 223, and 224 may respectively overlap the first to fourth contact blocks 211, 212, 213, and 214.

The size of each of the first to fourth moving blocks 221, 222, 223, and 224 may be less than the size of each of the first to fourth contact blocks 211, 212, 213, and 214. In such an embodiment, when viewed in one direction (e.g., the y direction), the first to fourth moving blocks 221, 222, 223, and 224 may not be viewed because they are hidden by the first to fourth contact blocks 211, 212, 213, and 214.

In another embodiment, the size of each of the first to fourth moving blocks 221, 222, 223, and 224 may be greater than the size of each of the first to fourth contact blocks 211, 212, 213, and 214. In such an embodiment, when viewed in one direction (e.g., the y direction), the first to fourth moving blocks 221, 222, 223, and 224 may be viewed as protruding beyond the outside of the first to fourth contact blocks 211, 212, 213, and 214, respectively. Hereinafter, for convenience of description, an embodiment in which the size of each of the first to fourth moving blocks 221, 222, 223, and 224 is less than the size of each of the first to fourth contact blocks 211, 212, 213, and 214 is shown and described in detail.

The second supporter 230 may be disposed on the lower end of the contact portion 210 and the moving portion 220. As an example, the 2-1 to 2-4 support blocks 231, 232, 233, and 234 may be disposed in a-z direction with respect to the third contact block 213, the third moving block 223, the fourth contact block 214, and the fourth moving block 224.

The 2-1 to 2-4 support blocks 231, 232, 233, and 234 may be arranged at equal intervals or different intervals in the x direction (e.g., the second direction DR2).

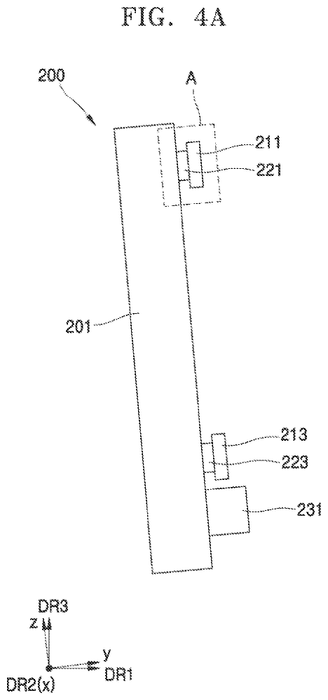

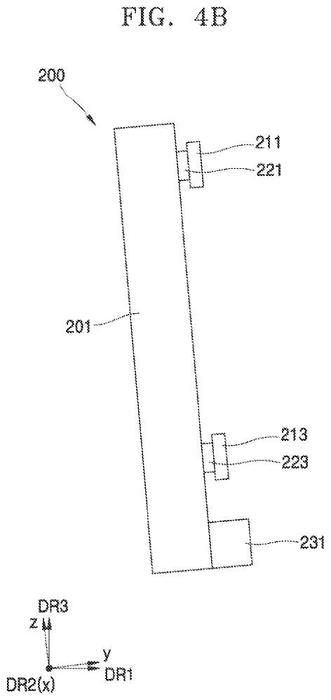

FIGS. 4A and 4B are schematic cross-sectional views of a portion of an apparatus for manufacturing a mask according to embodiments.

Referring to FIG. 4A, the apparatus 200 for manufacturing a mask may include the stage body portion 201 tilted with respect to one direction (e.g., the third direction DR3 or the direction of gravity). The first and third contact blocks 211 and 213 may protrude in the y direction from the surface of the stage body portion 201 facing the y direction.

The first and third moving blocks 221 and 223 may be respectively disposed between the first and third contact blocks 211 and 213 and the stage body portion 201. The 2-1 support block 231 may be disposed on the lower end of the third contact block 213 and the third moving block 223. As an example, the 2-1 support block 231 may be disposed in the −z direction with respect to the third contact block 213 and the third moving block 223.

The first contact block 211 and the first moving block 221 may be coupled to each other to form one body. The third contact block 213 and the third moving block 223 may be coupled to each other to form one body.

Although an embodiment in which the third contact block 213 is spaced apart from the 2-1 support block 231 is illustrated in FIG. 4A, the third contact block 213 may be in contact with the 2-1 support block 231.

The lower surface of the 2-1 support block 231 may not coincide with the lower surface of the stage body portion 201. As an example, one surface of the 2-1 support block 231 facing the −z direction and one surface of the stage body portion 201 facing the −z direction may not be arranged on the same plane.

In another embodiment, referring to FIG. 4B, the lower surface of the 2-1 support block 231 may coincide with the lower surface of the stage body portion 201. As an example, one surface of the 2-1 support block 231 facing the −z direction and one surface of the stage body portion 201 facing the −z direction may be arranged on the same plane.

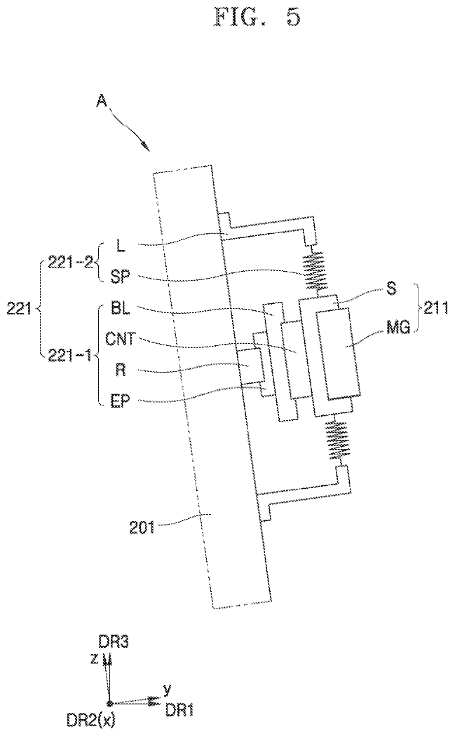

FIG. 5 is an enlarged cross-sectional view of a portion of an apparatus for manufacturing a mask according to an embodiment. FIG. 5 may be an enlarged cross-sectional view of the region A in FIG. 4A.

Hereinafter, although description is made in detail based on the first contact block 211 and the first moving block 221, the following characteristics are applicable to the second to fourth contact blocks and the second to fourth moving blocks.

Referring to FIG. 5, the first contact block 211 may include a socket S and a magnetic force portion MG.

The socket S may have an opening facing the one direction (e.g., the y direction), and at least a portion of the magnetic force portion MG may be disposed in the opening in the socket S. The opening in the socket S may be a blind-hole not passing the socket S.

In other words, the socket S may surround a portion of the magnetic force portion MG. In such an embodiment, the socket S may expose one surface of the magnetic force portion MG. As an example, the socket S may expose a surface of the magnetic force portion MG facing in the y direction.

Although an embodiment in which the magnetic force portion MG protrudes in the y direction from one surface of the socket S is shown in FIG. 5, the present disclosure is not limited thereto. In another embodiment, a surface of the magnetic force portion MG facing the y direction and a surface of the socket S facing the y direction may be arranged on the same plane.

The magnetic force portion MG may apply (or exert) a magnetic force. In an embodiment, the magnetic force portion MG may include an electropermanent magnet.

In such an embodiment, the magnetic force portion MG may have (or may exhibit) magnetic force when a current does not flow therethrough and may lose (or not may have or exhibit) magnetic force when a current flows therethrough. In another embodiment, the magnetic force portion MG may include an electromagnet. In such an embodiment, the magnetic force portion MG may have magnetic force when a current flows therethrough and may lose (or may not have) magnetic force when a current does not flow therethrough.

A wiring via which a current flows through the magnetic force portion MG may be further included. In an embodiment, the socket S may include a conductive material, and the wiring may be connected to the socket S. In such an embodiment, the current may flow to the magnetic force portion MG through the socket S.

The first moving block 221 may include a first translational moving portion 221-1 and a first elastic body 221-2.

The first translational moving portion 221-1 may translate the first contact block 211 on one surface of the stage body portion 201. As an example, the first translational moving portion 221-1 may move the first contact block 211 in the x direction and/or the z direction on the surface of the stage body portion 201 facing the y direction.

The first translational moving portion 221-1 may have various moving elements. Hereinafter, an embodiment in which a linear motion (LM) guide is provided as the first translational moving portion 221-1 is shown and described in detail.

The first translational moving portion 221-1 may include a rail R, an end plate EP, a block BL, and a connector CNT.

A rail R may be disposed on the stage body portion 201. The rail R may provide a path along which the first translational moving portion 221-1 may move. Accordingly, the rail R may be a portion of the first translational moving portion 221-1 that does not substantially move. The rail R may extend in a direction parallel to one surface of the stage body portion 201. As an example, the rail R may extend in the x direction (e.g., the second direction DR2). The rail R may extend in a direction (e.g., the z direction) tilted by an angle at which the stage body portion 201 is tilted with respect to the third direction DR3.

The end plate EP may be disposed on the rail R. The end plate EP may have a shape surrounding a portion of the rail R.

Although the rail R and the end plate EP are shown in an approximately quadrangular shape in FIG. 5, the present disclosure is not limited thereto. In an embodiment, the rail R may have an I-shape beam shape, and the end plate EP may have a shape clutching the upper end of the I-shape of the rail R. A plurality of metal balls forming an endless track may be provided between the end plate EP and the rail R. In such an embodiment, the metal balls may reduce frictional force between the end plate EP and the rail R.

The block BL may be disposed on the end plate EP. The block BL may act as a main body of the first translational moving portion 221-1 and may have a fastening groove or a screw groove for connecting to the contact portion 210.

In an embodiment, the end plate EP and the block BL may be integrally formed. As an example, the first translational moving portion 221-1 may include a T-shaped block BL directly coupled to the rail R. In such an embodiment, like the end plate EP described above, the lower end of the block BL may have a shape clutching the upper end of the rail R.

The connector CNT may be disposed between the block BL and the socket S. The connector CNT may include a bonding element connecting the block BL to the socket S.

In an embodiment, the connector CNT may be omitted or integrally formed with the block BL or the socket S. As an example, the socket S may include a fastening rib and may be directly coupled to the fastening groove in the block BL. In another embodiment, the block BL may have a fastening rib and may be directly coupled to the fastening groove in the socket S.

The first elastic body 221-2 may be disposed to correspond to the translational moving direction of the first contact block 211 and may apply external force in a direction opposite to the relevant direction. As an example, the first elastic body 221-2 may be connected to the first contact block 211 to apply external force in ±x direction and/or ±z direction.

The first elastic body 221-2 may have a structure of various shapes for applying (or configured to apply) external force. Hereinafter, for convenience of description, an embodiment in which a spring SP is included in the first elastic body 221-2 for applying elastic force is shown and described in detail.

The first elastic body 221-2 may include a spring SP and a leg L. The spring SP and the leg L may each be provided in a plurality.

The spring SP may be connected to one surface of the socket S. As an example, one of the plurality of springs SP may be connected to one surface of the socket S facing the +z direction, and another spring SP may be connected to one surface of the socket S facing the −z direction.

The spring SP may be configured to apply elastic force in a direction opposite to the moving direction of the first contact block 211. As an example, when the first contact block 211 moves in the +z direction, a spring SP connected to the surface of the socket S facing the +z direction is compressed and may apply elastic force the socket S in the −z direction. In such an embodiment, a spring SP connected to the surface of the socket S facing the −z direction is stretched and may apply elastic force to the socket S in the −z direction.

The springs SP may each be connected to a corresponding leg L. As an example, the leg L may be connected to the other end of the spring SP opposite to one end of the spring SP connected to the socket S.

One end of the leg L may be connected to the stage body portion 201.

The leg L connected and fixed to the stage body portion 201 may fix the spring SP such that the spring SP provides elastic force without moving along the first contact block 211 while the first contact block 211 moves.

In an embodiment, the other end of the leg L opposite to one end of the leg L connected to the spring SP may be connected to the stage body portion 201. In an embodiment, the leg L is connected to the spring SP in one end thereof and may extend in the −y direction and may be in contact with and coupled to the stage body portion 201. However, the present disclosure is not limited thereto and, as long as the spring SP is fixed to the stage body portion 201, there is no particular limitation to the shape of the leg L.

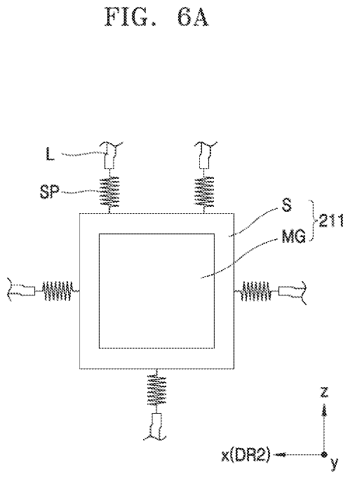

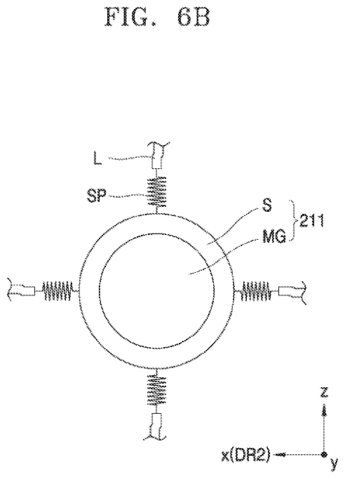

FIGS. 6A and 6B are enlarged front views of a portion of an apparatus for manufacturing a mask according to embodiments. FIGS. 6A and 6B may be enlarged front views of the region A in FIG. 4A.

Hereinafter, although description is made in detail based on the first contact block 211, the following characteristics are applicable to the second to fourth contact blocks 211, 212, 213, and 214 and the second to fourth moving blocks 221, 222, 223, and 224.

Referring to FIG. 6A, in an embodiment, the first contact block 211 may have an approximately quadrangular shape (e.g., a square). In such an embodiment, the socket S and the magnetic force portion MG may have an approximately quadrangular shape (e.g., a square). In another embodiment, the socket S may have a quadrangular shape, and the magnetic force portion MG may have a circular shape.

The spring SP and the leg L may each be provided in a plurality and connected to each corresponding surface of the socket S. As an example, the springs SP and the legs L may respectively correspond and may be connected to one surface of the socket S facing the +x direction, one surface of the socket S facing the −x direction, one surface of the socket S facing the +z direction, and one surface of the socket S facing the −z direction.

A connection structure of the spring SP and the leg L may be similar to or the same as that described above with reference to FIG. 5.

The number of springs SP connected to one of the surfaces of the socket S may be different from the number of springs SP connected to another one of the surfaces. As an example, the number of springs SP connected to one surface of the socket S facing the +z direction may be greater than the number of springs SP connected to one surface of the socket S facing the −z direction, the +x direction, or the −x direction. In an embodiment, a corresponding spring SP may be connected one by one to one surface of the socket S facing the −z direction, +x direction, or −x direction, and two springs SP may be connected to one surface of the socket S facing the +z direction.

A plurality of springs SP connected to one surface of the socket S facing the +z direction may provide compensation for gravity. Because the first contact block 211 has mass, the first contact block 211 will be acted on by gravity in the direction of gravity (e.g., the direction opposite to the third direction DR3, see FIG. 5). To compensate for this, an additional spring SP may be connected to one surface of the socket S facing the +z direction to apply force in the +z direction, which is approximately opposite to the direction of gravity. The additionally connected spring SP may compensate for the weight of the mask frame connected to the first contact block 211 using magnetic force as described below.

In another embodiment, one spring SP is connected to one surface of the socket S facing the +z direction, and the relevant spring SP may have a greater elastic coefficient than the spring SP connected to one surface of the socket S facing the −z direction, −x direction, or +x direction. Similar to the embodiment in which a plurality of springs SP are connected to one surface of the socket S facing the +z direction, this embodiment may compensate for gravity.

Referring to FIG. 6B, in an embodiment, the first contact block 211 may have an approximately circular shape. In such an embodiment, the socket S and the magnetic force portion MG may have an approximately circular shape. In another embodiment, the socket S may have a circular shape and the magnetic force portion MG may have an approximately diamond shape.

The spring SP and the leg L may each be provided in a plurality, attached to the socket S, and may extend in one direction. As an example, the plurality of springs SP may be attached to the socket S and may each extend in the +x direction, −x direction, +z direction, or −z direction. The plurality of legs L may be respectively connected to the plurality of springs SP corresponding thereto.

A spring SP extending in the +z direction may have a greater elastic coefficient than a spring SP extending in the +x direction, −x direction, or −z direction. In such an embodiment, the spring SP extending in the +z direction may compensate for gravity.

In another embodiment, similar to FIG. 6A, the spring SP and the leg L extending in the +z direction may each be provided in a plurality. As an example, two springs SP and two legs L may each be attached to the upper end (e.g., in the approximate +z direction) of the socket S and may extend in the +z direction.

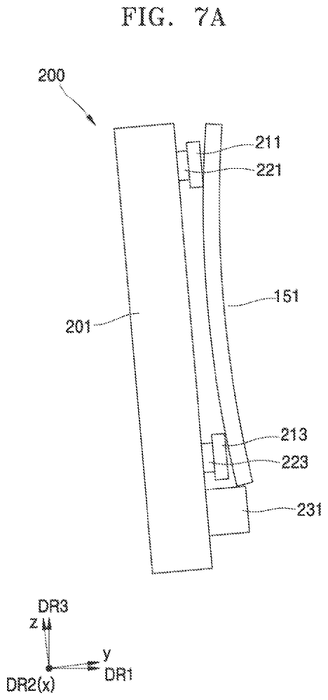

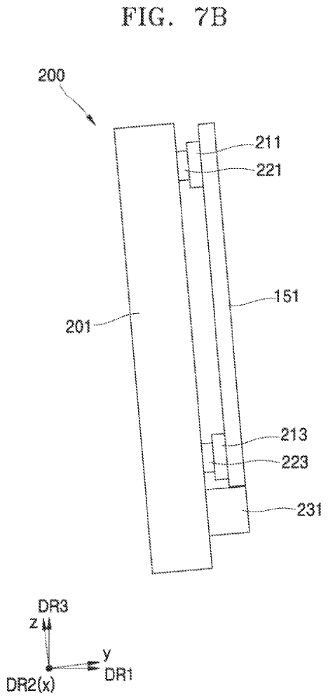

FIGS. 7A and 7B are schematic cross-sectional views showing states of an operating process of an apparatus for manufacturing a mask according to an embodiment.

Hereinafter, although description is made based on relationship between the first and third contact blocks 211 and 213, the first and third moving blocks 221 and 223, the 2-1 support block 231, and the mask frame 151, the following characteristics are applicable to the second and fourth contact blocks 212 and 214, the second and fourth moving blocks 222 and 224, and the 2-2 to 2-4 support blocks 232, 233, and 234 (see, e.g., FIG. 3).

Referring to FIG. 7A, the first and third contact blocks 211 and 213 may be in a state in which magnetic force is not present (or is not being exhibited). As an example, the first and third contact blocks 211 and 213 may include an electropermanent magnet, and with a current flowing therethrough, the first and third contact blocks 211 and 213 may not be applying magnetic force to the mask frame 151.

The mask frame 151 may be seated on the stage body portion 201. In this state, the 2-1 support block 231 may support the mask frame 151 in a direction (e.g., a direction opposite to the third direction DR3) opposite to the direction of gravity. A portion of each of the first and third contact blocks 211 and 213 may be in contact with the mask frame 151. In this state, because separate external force (e.g., magnetic force) is not applied to the mask frame 151, the first and third contact blocks 211 and 213 may not be in close contact with the mask frame 151.

Because the mask frame 151 has a characteristic of having a small thickness and has an opening, the mask frame 151 may be acted on by gravity in a direction opposite to the third direction DR3 to be curved in shape. As an example, bending due to gravity may occur in the upper portion of the mask frame 151 in the z direction. In an embodiment, the mask frame 151 may sag approximately in the −y direction.

In this state, when the mask sheet is welded and the mask assembly is manufactured, one surface of the mask frame 151 and one surface of the mask sheet are not parallel to each other, and thus, welding may be incompletely performed. In addition, even when welding is performed, due to bending of the mask frame 151, the positional accuracy of the mask sheet may decrease due to the curvature of the mask frame 151. This may lead to a decrease in the precision of the deposition material pattern described above with reference to FIG. 1. Accordingly, the mask frame 151 should be flattened (or made flat) in one direction (e.g., the z direction).

Referring to FIG. 7B, the first and third contact blocks 211 and 213 may be in a state of applying magnetic force to the mask frame 151. As an example, the first and third contact blocks 211 and 213 may include an electropermanent magnet, and with a current not flowing therethrough, the first and third contact blocks 211 and 213 may be applying magnetic force to the mask frame 151.

In this state, the mask frame 151 may be in close contact with the first and third contact blocks 211 and 213. The mask frame 151 may be stretched in the z direction. Because sagging of the mask frame 151 in the approximately-y direction may be removed, and other bending may also be removed, the mask frame 151 may be flat along one direction (e.g., the z direction).

The lower surface (or the surface facing the −z direction) of the mask frame 151 may be supported by the 2-1 support block 231.

After the first and third contact blocks 211 and 213 are in close contact with the mask frame 151 by applying magnetic force to the mask frame 151, the first and third moving blocks 221 and 223 may move the first and third contact blocks 211 and 213. In this state, the mask frame 151 may be additionally stretched and flatness may be improved even more.

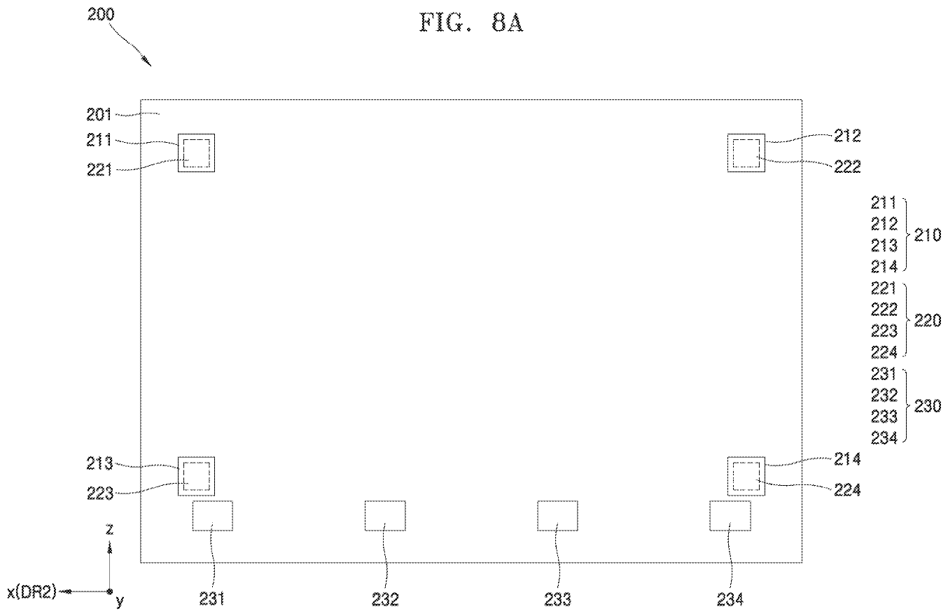

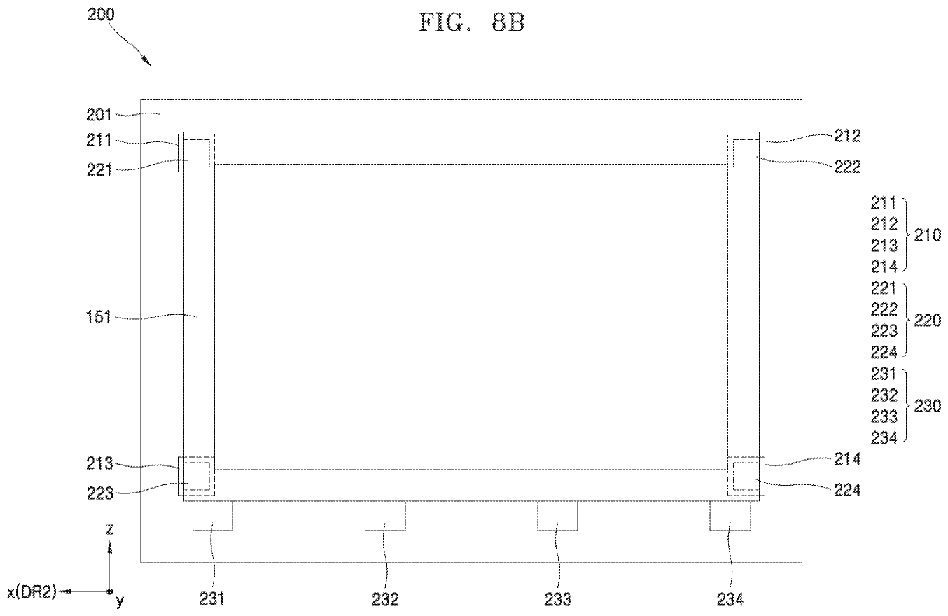

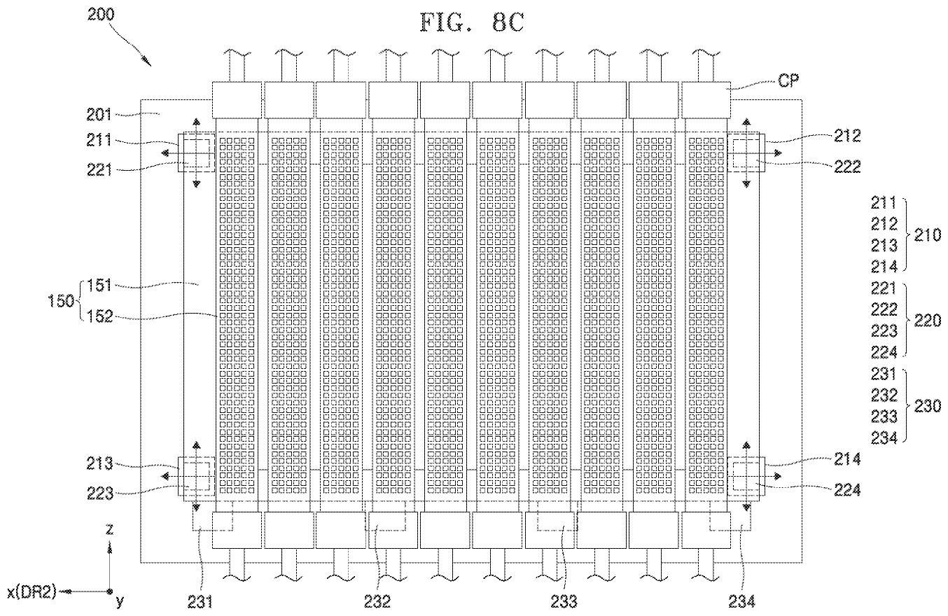

FIGS. 8A to 8C are schematic front views showing states corresponding to steps of a method of manufacturing a mask according to an embodiment.

Referring to FIG. 8A, before the mask frame is arranged, the apparatus 200 for manufacturing a mask may be prepared. The apparatus 200 for manufacturing a mask may include the stage body portion 201, the contact portion 210, the moving portion 220, and the second supporter 230. The characteristics of the apparatus 200 for manufacturing a mask may be the same as those described above with reference to FIGS. 2 and 3.

Referring to FIG. 8B, the mask frame 151 may be seated on the apparatus 200 for manufacturing a mask.

The contact portion 210 may include the first to fourth contact blocks 211, 212, 213, and 214. The first to fourth contact blocks 211, 212, 213, and 214 may be respectively arranged to correspond to edges of the mask frame 151. A portion of each of the first to fourth contact blocks 211, 212, 213, and 214 may overlap the mask frame 151.

The first to fourth contact blocks 211, 212, 213, and 214 may be in close contact with the mask frame 151 by applying magnetic force to the mask frame 151. In this state, the mask frame 151 may be stretched to become flat, and a process thereof may be the same as that described above with reference to FIGS. 7A and 7B.

The first to fourth moving blocks 221, 222, 223, and 224 may be arranged to respectively correspond to the first to fourth contact blocks 211, 212, 213, and 214. The first to fourth moving blocks 221, 222, 223, and 224 may respectively overlap the first to fourth contact blocks 211, 212, 213, and 214.

The first to fourth moving blocks 221, 222, 223, and 224 may additionally stretch the mask frame 151 by moving the first to fourth contact blocks 211, 212, 213, and 214 in the ±x direction and/or the ±z direction.

Through the process in which the mask frame 151 is in close contact with the first to fourth contact blocks 211, 212, 213, and 214 and the process in which the mask frame 151 is additionally stretched by the first to fourth moving blocks 221, 222, 223, and 224, the mask frame 151 may be spread flat and flatness thereof may be maintained during a process of welding the mask sheet, which will be described below.

Referring to FIG. 8C, while stretched, the mask sheet 152 may be disposed on the mask frame 151.

When the mask sheet 152 is formed as one (e.g., when only one mask sheet 152 is present), the mask sheet 152 may be formed in a quadrangle. With each side of the mask sheet 152 stretched by using a clamp unit CP, the mask sheet 152 may be fixed to the mask frame 151 by performing welding on each wall of the mask sheet 152. In another embodiment, when the mask sheet 152 is provided in a plurality, the mask sheets 152 may have a rectangular shape, and the mask sheets 152 may be stretched in a lengthwise direction thereof (e.g., the ±z direction) by holding ends (e.g., the ends in the ±z direction) of the long sides of the mask sheets 152 by using the clamp unit CP. Then, the ends of the mask sheet 152 may be fixed to the mask frame 151 by welding and the like. While stretched, the mask sheet 152 may be fixed to the mask frame 151.

In this state, when the contact portion 210 that is in contact with the mask

frame 151 is fixed to the stage body portion 201, a frictional resistance may occur with the mask sheet 152. In an embodiment, because, while stretched, the mask sheet 152 is fixed to the mask frame 151, a force that would return to the state before being stretched (e.g., a force restoring acting in the ±z direction) may act on the mask frame 151. In this state, when the contact portion 210 is fixed to the stage body portion 201, frictional force may act on the mask sheet 152 and/or the mask frame 151. This may cause a partial transformation of the mask sheet 152 and/or the mask frame 151 and may decrease the precision of the mask.

The moving portion 220 may reduce the frictional resistance. In an embodiment, the moving portion 220 may include a translational mover that may translate the contact portion 210. Accordingly, a frictional resistance against force (e.g., force applied in the ±z direction) applied to the mask frame 151 by the mask sheet 152 may be reduced. However, in this case, because force may be applied in the ±z direction, the mask frame 151 may be transformed (e.g., may be bent) in the ±z direction. To prevent this, the moving portion 220 may include the elastic body described above with reference to FIG. 5. The elastic body may cancel (or may oppose) a force applied to the mask frame 151 by the mask sheet 152 by using elastic force. Accordingly, the moving portion 220 may be configured to reduce a frictional resistance applied to the mask sheet 152 and the mask frame 151 while cancelling (or opposing) the force applied to the mask frame 151 by the mask sheet 152.

Through the above process, when attaching the mask sheet 152 to the mask frame 151, the flatness of the mask frame 151 may be maintained and transformation may be reduced, and thus, precision may be improved.

After attaching the mask sheet 152 to the mask frame 151, the end of the mask sheet 152 may be cut off by using a separate cutting unit. As an example, after attaching the mask sheet 152 to the mask frame 151, the clamp unit CP is removed and a portion of the mask sheet 152 may be cut off such that one surface (e.g., a surface facing the ±z direction) of the mask frame 151 coincides with one surface (e.g., a surface facing the ±z direction) of the mask sheet 152.

When the end of the mask sheet 152 is cut off, the mask assembly 150 may be fully formed. The mask assembly 150 may be disposed inside the apparatus 100 for manufacturing a display apparatus as described above with reference to FIG. 1. Through this, the mask sheet 152 may be fixed to the mask frame 151 in an environment similar to an environment in which the actual mask assembly 150 is used.

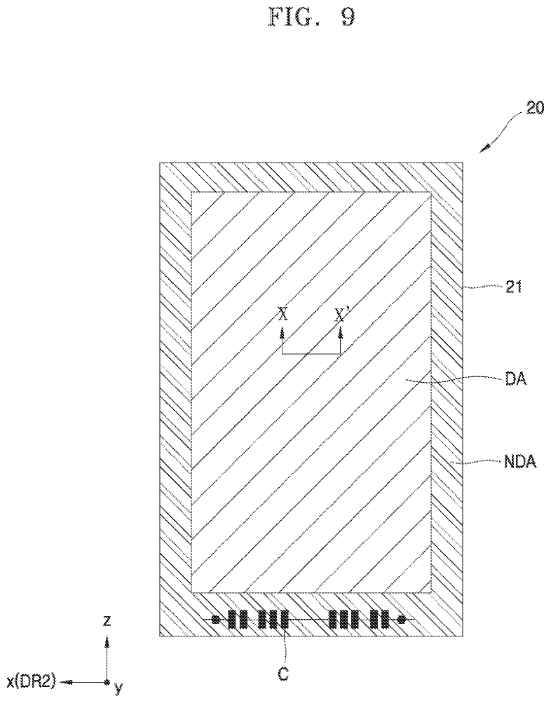

FIG. 9 is a schematic plan view of a display apparatus according to an embodiment. FIG. 10 is a cross-sectional view of the display apparatus shown in FIG. 9 taken along the line X-X′ of FIG. 9.

Referring to FIGS. 9 and 10, a display apparatus 20 may have a display area DA and a non-display area NDA outside the display area DA defined in a substrate 21. An organic light-emitting element 28 may be arranged in the display area DA. A power line and the like may be arranged in the non-display area NDA. In addition, a pad portion C may be arranged in the non-display area NDA.

The display apparatus 20 may include the display substrate D, an intermediate layer 28-2 disposed over the display substrate D, and an opposite electrode 28-3 disposed on the intermediate layer 28-2. The display apparatus 20 may include a thin-film encapsulation layer E formed on the opposite electrode 28-3.

The display substrate D may include the substrate 21, a buffer layer 22, a thin-film transistor TFT, a gate insulating layer 24, an interlayer insulating layer 26, a passivation layer 27, and a sub-pixel electrode (e.g., an anode electrode) 28-1.

The substrate 21 may include a plastic material or a metal material, such as SUS and Ti. In addition, the substrate 21 may include a polymer, such as polyimide (PI). Hereinafter, for convenience of description, an embodiment in which the substrate 21 includes polyimide is primarily described in detail.

The thin-film transistor TFT may be disposed over the substrate 21, the passivation layer 27 may be disposed to cover the thin-film transistor TFT, and the organic light-emitting element 28 may be disposed on the passivation layer 27.

The buffer layer 22 may be disposed on the upper surface of the substrate 21. The buffer layer 22 includes an organic compound and/or an inorganic compound. The buffer layer 22 may include silicon oxide (SiOₓ), silicon nitride (SiNₓ), or silicon oxynitride (SiON).

An active layer 23 is formed in a pattern (e.g., a preset or predetermined pattern) on the buffer layer 22, and then, the active layer 23 may be buried by the gate insulating layer 24. The active layer 23 may have a source region 23-1 and a drain region 23-3 and a channel region 23-2 therebetween.

The active layer 23 may be formed to include various materials. As an example, the active layer 23 may include an inorganic semiconductor material, such as amorphous silicon or crystalline silicon. As another example, the active layer 23 may include an oxide semiconductor. As another example, the active layer 23 may include an organic semiconductor material. Hereinafter, for convenience of description, an embodiment in which the active layer 23 includes amorphous silicon is primarily described in detail.

The active layer 23 may be formed by forming an amorphous silicon layer on the buffer layer 22, crystallizing the amorphous silicon layer to form a polycrystalline silicon layer, and patterning the polycrystalline silicon layer. A source region 23-1 and a drain region 23-3 of the active layer 23 may be doped with impurities depending on the kind of thin-film transistor, such as a driving thin-film transistor and a switching thin-film transistor.

A gate electrode 25 and the interlayer insulating layer 26 may be disposed on the gate insulating layer 24. The gate electrode 25 corresponds to the active layer 23, and the interlayer insulating layer 26 buries the gate electrode 25. The gate electrode 25 may be arranged to overlap the channel region 23-2 of the active layer 23.

Contact holes (e.g., contact openings) H1 are formed in the interlayer insulating layer 26 and the gate insulating layer 24, and then, a source electrode 27-1 and a drain electrode 27-2 may be disposed on the interlayer insulating layer 26 to respectively be in contact with the source region 23-1 and the drain region 23-3.

The passivation layer 27 may be disposed on the thin-film transistor TFT, and the sub-pixel electrode 28-1 of the organic light-emitting element 28 may be disposed on the passivation layer 27. The sub-pixel electrode 28-1 may be in contact with the drain electrode 27-2 of the thin-film transistor TFT through a via hole (e.g., a via opening) H2 formed in the passivation layer 27. The passivation layer 27 may include a single layer or multiple layers. The passivation layer 27 may include a planarization layer such that an upper surface of the passivation layer 27 is flat regardless of the curvature of the lower layers or may be formed to be curved according to (or corresponding to) the curvature of the lower layers.

The sub-pixel electrode 28-1 is disposed on the passivation layer 27, and then, the pixel-defining layer 29 may be disposed to cover the sub-pixel electrode 28-1 and the passivation layer 27. The pixel-defining layer 29 may have an opening to expose a portion of the sub-pixel electrode 28-1.

The intermediate layer 28-2 and the opposite electrode 28-3 may be disposed on the sub-pixel electrode 28-1. In another embodiment, the opposite electrode 28-3 may be formed on the entire surface of the display substrate D. The opposite electrode 28-3 may be formed on the intermediate layer 28-2 and the pixel-defining layer 29. Hereinafter, for convenience of description, an embodiment in which the opposite electrode 28-3 is formed on the intermediate layer 28-2 and the pixel-defining layer 29 is primarily described in detail.

The sub-pixel electrode 28-1 may act as an anode electrode, and the opposite electrode 28-3 may act as a cathode electrode. However, the polarities of the subpixel electrode 28-1 and the counter electrode 28-3 may be reversed.

The sub-pixel electrode 28-1 is insulated from the opposite electrode 28-3 by the intermediate layer 28-2. An organic emission layer may be configured to emit light by applying voltages of different polarities to the intermediate layer 28-2.

The intermediate layer 28-2 may include the organic emission layer. In an embodiment, the intermediate layer 28-2 may include the organic emission layer and may further include at least one of a hole injection layer (HIL), a hole transport layer (HTL), an electron transport layer (ETL), and an electron injection layer (EIL). However, the present disclosure is not limited thereto, and the intermediate layer 28-2 may include an organic emission layer and may further include other various functional layers.

The intermediate layer 28-2 may be formed by the apparatus 100 for manufacturing a display apparatus described above with reference to FIG. 1.

The intermediate layer 28-2 may be provided in a plurality. The plurality of intermediate layers 28-2 may form (or may define) the display area DA. In this case, the plurality of intermediate layers 28-2 may be arranged to be spaced apart from each other in the display area DA.

One unit pixel may include a plurality of sub-pixels. The plurality of sub-pixels may be configured to emit light of various colors. As an example, the plurality of sub-pixels may include sub-pixels respectively configured to emit red, green, and blue light or sub-pixels respectively configured to emit red, green, blue, and white light.

The sub-pixel may include one intermediate layer 28-2. In the case of forming one sub-pixel, the intermediate layer 28-2 may be formed by using the apparatus for manufacturing a display apparatus.

A thin-film encapsulation layer E may include a plurality of inorganic layers or may include an inorganic layer and an organic layer.

The organic layer of the thin-film encapsulation layer E may include a single layer or stacked layers including a polymer. As an example, the organic layer of the thin-film encapsulation layer E may be at least one of polyethylene terephthalate (PET), polyimide (PI), polycarbonate (PC), an epoxy, polyethylene (PE), and polyacrylate (PA).

The inorganic layer of the thin-film encapsulation layer E may include a single layer or a stacked layer including metal oxide or metal nitride. As an example, the inorganic layer of the thin-film encapsulation layer E may include one of silicon nitride (SiNₓ), aluminum oxide (e.g., Al₂O₃), silicon oxide (e.g., SiO₂), and titanium oxide (e.g., TiO₂).

An uppermost layer of the thin-film encapsulation layer E exposed to the outside may include an inorganic layer to prevent moisture transmission to the organic light-emitting element.

The thin-film encapsulation layer E may include at least one sandwich

structure in which at least one organic layer is disposed between at least two inorganic layers. In another embodiment, the thin-film encapsulation layer E may include at least one sandwich structure in which at least one inorganic layer is disposed between at least two organic layers. In another embodiment, the thin-film encapsulation layer E may include a sandwich structure in which at least one organic layer is disposed between at least two inorganic layers, and a sandwich structure in which at least one inorganic layer is disposed between at least two organic layers.

The thin-film encapsulation layer E may sequentially include a first inorganic layer, a first organic layer, and a second inorganic layer from the upper portion of the organic light-emitting element OLED.

In another embodiment, the thin-film encapsulation layer E may sequentially include a first inorganic layer, a first organic layer, a second inorganic layer, a second organic layer, and a third inorganic layer from the upper portion of the organic light-emitting element OLED.

In another embodiment, the thin-film encapsulation layer E may sequentially include a first inorganic layer, a first organic layer, a second inorganic layer, a second organic layer, a third inorganic layer, a third organic layer, and a fourth inorganic layer from the upper portion of the organic light-emitting element OLED.

According to an embodiment, an apparatus for manufacturing a mask may be provided which improves flatness of a mask by stretching the mask frame by using the contact portion that is in contact with the mask frame during vertical tension welding, and a moving portion configured to move the contact portion is provided, and thus, frictional force applied while the mask sheet is attached is reduced. However, the scope of the present disclosure is not limited by these aspects and features.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. An apparatus for manufacturing a mask, the apparatus comprising:
a stage body portion tilted with respect to a gravitational direction and configured to receive a mask frame having opening sits thereon;
a contact portion protruding from one surface of the stage body portion toward the mask frame; and
a moving portion configured to move the contact portion.

2. The apparatus of claim 1, wherein at least a portion of the contact portion overlaps the mask frame.

3. The apparatus of claim 1, wherein the contact portion is arranged to correspond to an edge of the mask frame.

4. The apparatus of claim 1, wherein the contact portion comprises a magnet.

5. The apparatus of claim 4, wherein the magnet of the contact portion is configured to exhibit no magnetism while a current flows therethrough.

6. The apparatus of claim 1, wherein the moving portion is between the contact portion and the stage body portion.

7. The apparatus of claim 1, wherein the moving portion comprises a translation element.

8. The apparatus of claim 1, wherein the moving portion comprises an elastic body corresponding to at least one of moving directions of the contact portion, the elastic body being configured to apply an elastic force to the contact portion.

9. The apparatus of claim 8, wherein the contact portion has a plurality of surfaces,
wherein the elastic body is provided in a plurality, and
wherein each surface of the contact portion is connected to at least one elastic body corresponding thereto.

10. The apparatus of claim 9, wherein a number of elastic bodies connected to one of the plurality of surfaces is different from a number of elastic bodies connected to another one of the plurality of surfaces.

11. The apparatus of claim 1, further comprising a second supporter protruding from one surface of the stage body portion and configured to support one surface of the mask frame.

12. A method of manufacturing a mask, the method comprising:
arranging a mask frame having an opening on a mask stage that is tilted with respect to a gravitational direction; and
attaching a mask sheet to the mask frame,
wherein the mask stage comprises:
a stage body portion;
a contact portion protruding from one surface of the stage body portion toward the mask frame; and
a moving portion configured to move the contact portion.

13. The method of claim 12, further comprising seating the mask frame on a second supporter protruding from one surface of the mask stage.

14. The method of claim 12, further comprising allowing the mask frame to be in close contact with the contact portion by using a magnet provided to the contact portion.

15. The method of claim 14, wherein the magnet of the contact portion is configured to exhibit no magnetism while a current flows therethrough.

16. The method of claim 12, further comprising stretching the mask frame.

17. The method of claim 12, wherein the moving portion comprises an elastic body configured to apply elastic force and corresponding to at least one of moving directions of the contact portion.

18. The method of claim 12, wherein the contact portion is arranged to correspond to an edge of the mask frame.

19. The method of claim 12, wherein at least a portion of the contact portion overlaps the mask frame.

20. The method of claim 12, further comprising moving the mask frame relative to the mask stage.
